(19) United States
(12) Patent Application Publication
(10) Pub. No.: US 2026/0344264 A1
(43) Pub. Date: Oct. 29, 2026

(54) DISPLAY DEVICE AND METHOD OF MANUFACTURING THE DISPLAY DEVICE

(71) Applicant: Samsung Display Co., LTD., Yongin-si (KR)

(72) Inventor: Jong Seok HAN, Yongin-si (KR)

(21) Appl. No.: 19/413,148

(22) Filed: Dec. 9, 2025

(30) Foreign Application Priority Data
Apr. 24, 2025 (KR) 10-2025-0053636

(51) Int. Cl. H10K 59/80; H10K 59/12; H10K 59/50; H10K 102/00

(52) U.S. Cl. CPC H10K 59/879; H10K 59/1201; H10K 59/50; H10K 59/873; H10K 2102/351

(57) ABSTRACT

A display device includes a substrate including a non-emission area and a first emission area, a second emission area, and a third emission area adjacent to each other but spaced apart from each other by the non-emission area located between the first emission area, the second emission area, and the third emission area; a light emitting element located on the substrate; a capping layer located on the light emitting element; an encapsulation layer located on the capping layer; and a color control member located on the encapsulation layer. The light emitting element includes: a functional layer located on the substrate; a first light emitting layer, a second light emitting layer, and a third light emitting layer located on the functional layer and overlapping the first emission area, the second emission area, and the third emission area, respectively, wherein the functional layer has a thickness of 1280 Å to 1480 Å.

This application claims priority to Korean Patent Application No. 10-2025-0053636, filed on Apr. 24, 2025, and all the benefits accruing therefrom under 35 U.S.C. §119, the content of which in its entirety is herein incorporated by reference.

### BACKGROUND

### 1. Field

The present disclosure relates to a display device and a method of manufacturing the display device.

### 2. Description of the Related Art

As the information society develops, demands for display devices for displaying images are increasing in various forms. Accordingly, various types of display devices, including organic light emitting display devices, are being developed.

Organic light emitting display devices are self-luminous display devices that electrically excite fluorescent organic compounds to emit light. These display devices can be driven at low voltages and can be made thin. In addition, organic light emitting display devices have recently attracted attention because they can provide wide viewing angles and fast response speeds, solving drawbacks that are pointed out as problems in liquid crystal display devices.

However, in the organic light emitting display devices, a white angular dependency (WAD) phenomenon according to a viewing angle can be a problem. WAD is a phenomenon in which when an organic electroluminescent portion of an organic light emitting display device emits light, white is perceived from the front, but blue is perceived from the side. This is because when the organic electroluminescent portion emits light, the wavelength changes due to a change in interference length caused by a resonance structure.

Therefore, the color reproducibility of the display device is reduced when viewed from the side compared with when viewed from the front. When the color reproducibility is reduced, an image cannot be displayed accurately. Therefore, the image quality of the display device deteriorates.

### SUMMARY

Aspects of the present disclosure provide a display device with improved display quality.

Aspects of the present disclosure also provide a method of manufacturing a display device with improved display quality.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate including a non-emission area and a first emission area, a second emission area, and a third emission area adjacent to each other but spaced apart from each other by the non-emission area located between the first emission area, the second emission area, and the third emission area; a light emitting element located on the substrate; a capping layer located on the light emitting element; an encapsulation layer located on the capping layer; and a color control member located on the encapsulation layer, wherein the light emitting element includes: a functional layer located on the substrate; a first light emitting layer, a second light emitting layer, and a third light emitting layer located on the functional layer and overlapping the first emission area, the second emission area, and the third emission area, respectively, wherein the functional layer has a thickness of 1280 Å to 1480 Å.

In an embodiment, light emitting element further includes: a first sub-functional layer located between the functional layer and the first light emitting layer and overlapping the first emission area; and a second sub-functional layer located between the functional layer and the second light emitting layer and overlapping the second emission area.

In an embodiment, a thickness of the first sub-functional layer and a thickness of the second sub-functional layer are different from each other.

In an embodiment, the thickness of the first sub-functional layer is greater than the thickness of the second sub-functional layer.

In an embodiment, the first sub-functional layer has a thickness of 600 Å to 800 Å, and the second sub-functional layer has a thickness of 400 Å to 600 Å.

In an embodiment, the capping layer has a refractive index of 1.9 to 2.3 and a thickness of 600 Å to 900 Å.

In an embodiment, the capping layer includes a first capping layer located on the light emitting element, a second capping layer located on the first capping layer, and a third capping layer located on the second capping layer, wherein the first capping layer has a first refractive index, the second capping layer has a second refractive index, and the third capping layer has a third refractive index.

In an embodiment, the first refractive index and the third refractive index are different from the second refractive index.

In an embodiment, the first refractive index and the third refractive index are smaller than the second refractive index.

In an embodiment, the first refractive index and the third refractive index have a value of 1.5 to 1.8, and the second refractive index has a value of 1.9 to 2.3.

In an embodiment, a thickness of the first capping layer, a thickness of the second capping layer, and a thickness of the third capping layer are different from each other.

In an embodiment, the thickness of the first capping layer is smaller than the thickness of the third capping layer, and the thickness of the third capping layer is smaller than the thickness of the second capping layer.

In an embodiment, the first capping layer has a thickness of 50 Å to 200 Å, the second capping layer has a thickness of 350 Å to 500 Å, and the third capping layer has a thickness of 200 Å to 300 Å.

In an embodiment, the color control member has a light transmittance for light traveling in a thickness direction of the color control member and a light transmittance for light traveling in a direction intersecting the thickness direction of the color control member.

In an embodiment, the light transmittance in the thickness direction of the color control member is higher than the light transmittance in the direction intersecting the thickness direction of the color control member.

In an embodiment, each of the light transmittances is the transmittance of light in a blue wavelength range.

In an embodiment, each of the light transmittances is the transmittance of light in a green wavelength range.

In an embodiment, each of the light transmittances is the transmittance of light in a red wavelength range.

According to an aspect of the present disclosure, a method of manufacturing a display device includes performing a deposition and encapsulation process operation which includes forming a substrate, a light emitting element located on the substrate, a capping layer located on the light emitting element, and an encapsulation layer located on the capping layer, performing a visual inspection operation which includes measuring a viewing angle color shift of light emitted from the light emitting element and passing through the capping layer and the encapsulation layer, and performing a viewing angle color shift dispersion adjustment operation based on determining a dispersion of the viewing angle color shift measured in the visual inspection operation is defective, wherein the viewing angle color shift dispersion adjustment operation includes forming a color control member on the encapsulation layer.

According to an aspect of the present disclosure, an electronic device includes a display device which displays an image; and a processor which transmits an image data signal for displaying the image to the display device, wherein the display device includes: a substrate including a non-emission area; and a first emission area, a second emission area, and a third emission area adjacent to each other but spaced apart from each other by the non-emission area located between the first emission area, the second emission area, and the third emission area; a light emitting element located on the substrate; a capping layer located on the light emitting element; an encapsulation layer located on the capping layer; and a color control member located on the encapsulation layer. The light emitting element includes: a functional layer located on the substrate; a first light emitting layer, a second light emitting layer, and a third light emitting layer located on the functional layer and overlapping the first emission area, the second emission area, and the third emission area, respectively, wherein the functional layer has a thickness of 1280 Å to 1480 Å.

According to embodiments, embodiments of the present disclosure improve a viewing angle color shift (VACS) dispersion defect of a display device and thus provide a display device with improved display quality.

However, the effects of the present disclosure are not restricted to the one set forth herein. The above and other effects of the present disclosure will become more apparent to one of daily skill in the art to which the present disclosure pertains by referencing the detailed description of the present disclosure given below.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic plan view of a display device according to an embodiment;

FIG. 2 is an equivalent circuit diagram of a pixel according to an embodiment;

FIG. 3 is a plan view illustrating the schematic arrangement of a plurality of pixels in a display area of FIG. 1;

FIG. 4 is a schematic cross-sectional view of the display device according to the embodiment, taken along line X1-X1’ of FIG. 3;

FIG. 5 is a schematic view of the display device of FIG. 4;

FIG. 6 is an enlarged cross-sectional view of portion B1 of FIG. 5;

FIG. 7 is a schematic view of a first dichroic dye in FIG. 6;

FIG. 8 is a schematic view of a display device according to an embodiment;

FIG. 9 illustrates the viewing angle color shift (VACS) of the display devices of FIGS. 5 and 8;

FIG. 10 illustrates the white angular dependency (WAD) of the display device of FIG. 8;

FIG. 11 illustrates the WAD of the display device of FIG. 5;

FIG. 12 is an enlarged cross-sectional view of portion B1 of FIG. 5 of a display device according to an embodiment;

FIG. 13 is a schematic view of a second dichroic dye;

FIG. 14 is an enlarged cross-sectional view of portion B1 of FIG. 5 of a display device according to an embodiment;

FIG. 15 is a schematic view of a third dichroic dye;

FIG. 16 is a schematic view of a display device according to an embodiment;

FIG. 17 is a cross-sectional view of a display device according to an embodiment, taken along line X1-X1’ of FIG. 3;

FIG. 18 is a schematic view of the display device of FIG. 17;

FIG. 19 illustrates the VACS of the display device of FIGS. 17 and 18;

FIG. 20 is a cross-sectional view of a display device according to an embodiment, taken along line X1-X1’ of FIG. 3;

FIG. 21 is a schematic view of the display device of FIG. 20;

FIG. 22 illustrates the VACS of the display device of FIGS. 20 and 21;

FIG. 23 is a cross-sectional view of a display device according to an embodiment, taken along line X1-X1’ of FIG. 3;

FIG. 24 is a flowchart schematically illustrating a method of manufacturing a display device according to an embodiment;

FIG. 25 is a flowchart illustrating a VACS dispersion adjustment operation according to an embodiment;

FIG. 26 is a block diagram of an electronic device according to an embodiment; and

FIG. 27 is a schematic diagram of electronic devices according to various embodiments.

### DETAILED DESCRIPTION

Embodiments supported by the present disclosure will now be described more fully hereinafter with reference to the accompanying drawings, in which example embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will filly convey the scope of example aspects of the present disclosure to those skilled in the art.

It will also be understood that when a layer is referred to as being "on" another layer or substrate, it can be directly on the other layer or substrate, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings of the present invention. Similarly, the second element could also be termed the first element.

It is to be understood that characteristics described herein with respect to relative terms such as, for example, “high,” “low,” “large,” “small,” and the like refer to the characteristics satisfying (e.g., being greater than, less than, or the like) a threshold associated with the characteristics.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described in detail with reference to the accompanying drawings.

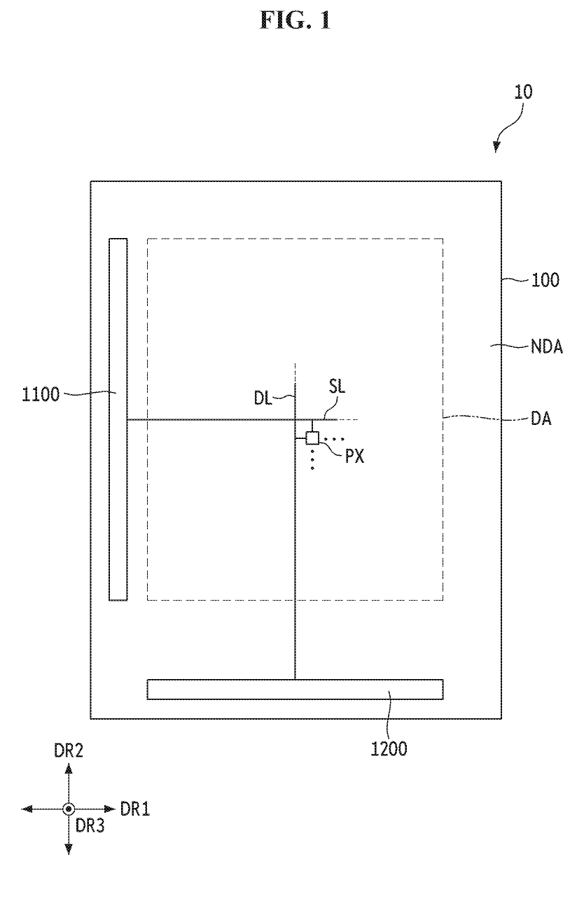

FIG. 1 is a schematic plan view of a display device 10 according to an embodiment.

Referring to FIG. 1, the display device 10 according to the embodiment may include a substrate 100 and pixels PX located on the substrate 100. The display device 10 may further include a scan driver 1100 and a data driver 1200 which are electrically connected to the pixels PX. The scan driver 1100 and the data driver 1200 may be located on the substrate 100, but embodiments are not limited to this case. For example, at least one of the scan driver 1100 and the data driver 1200 may be located on a circuit board (e.g., an FPCB) electrically connected to pads located on the substrate 100.

The substrate 100 may be a base layer for manufacturing or providing the display device 10 and may form a support for a display panel including the pixels PX. The substrate 100 may include a display area DA and a non-display area NDA around the display area DA. The display area DA may be an area where the pixels PX are located and may be an area where an image is displayed by the pixels PX. The non-display area NDA may be an area other than the display area DA and may be located around the display area DA. For example, the non-display area NDA may surround the display area DA.

In FIG. 1, a first direction DR1, a second direction DR2, and a third direction DR3 are defined. In an embodiment, the first direction DR1 may be a horizontal direction of the display device 10 (or the substrate 100), and the second direction DR2 may be a vertical direction of the display device 10. The third direction DR3 may be a thickness direction of the display device 10.

In FIG. 1, the substrate 100 and the display area DA have a quadrangular shape in a plan view, but embodiments are not limited to this shape. For example, the shape of the substrate 100 and the display area DA may vary depending on embodiments. In some aspects, in FIG. 1, corner portions of the substrate 100 and the display area DA are angled. However, embodiments are not limited to this case. For example, the substrate 100 and the display area DA may include angled or rounded corner portions.

In the display area DA, the pixels PX and lines (or portions of the lines) connected to the pixels PX may be located. For example, the pixels PX, scan lines SL, and data lines DL may be located in the display area DA. In the description of embodiments, the term “connection” may include the meaning of electrical connection and/or physical connection. In FIG. 1, one pixel PX and one scan line SL and one data line DL connected to the pixel PX are illustrated. However, a plurality of pixels PX and a plurality of scan lines SL and a plurality of data lines DL connected to the pixels PX may be located in the display area DA.

The pixels PX may be further connected to additional lines. For example, each of the pixels PX may be further connected to a first power line to which a first power supply voltage is applied and a second power line to which a second power supply voltage is applied. The type or number of lines connected to each pixel PX may vary depending on the configuration of the pixel PX (e.g., the structure or operation method of a pixel circuit).

The lines connected to the pixels PX (e.g., portions of the lines extending from the display area DA to the non-display area NDA) may be located in the non-display area NDA. In an embodiment, the scan driver 1100 and the data driver 1200 may be located in the non-display area NDA.

The scan driver 1100 may be connected to the pixels PX through the scan lines SL. The scan driver 1100 may supply scan signals to the pixels PX. In an embodiment, the scan driver 1100 may be formed on the substrate 100 together with the pixels PX, but embodiments are not limited to this case.

Although FIG. 1 discloses an embodiment in which the scan driver 1100 is placed on a single side (e.g., a left side) of the display area DA, embodiments are not limited to this case. For example, the scan driver 1100 may also be placed on both sides (e.g., left and right sides) of the display area DA. Alternatively, the scan driver 1100 may be placed on a circuit board electrically connected to the pixels PX through pads located on the substrate 100.

The data driver 1200 may be connected to the pixels PX through the data lines DL. The data driver 1200 may supply data signals. In an embodiment, the data driver 1200 may be formed as an integrated circuit (IC) chip and placed or mounted on the substrate 100. However, embodiments are not limited to this case. For example, the data driver 1200 may also be placed on a circuit board electrically connected to the pixels PX through pads located on the substrate 100.

In an embodiment, the display device 10 may be a light emitting display device such as an organic light emitting display device including an organic light emitting diode, a quantum dot light emitting display device including a quantum dot light emitting layer, an inorganic light emitting display device including an inorganic semiconductor, or an ultrasmall light emitting display device including an ultrasmall light emitting diode such as a micro- or nano-light emitting diode. However, embodiments are not limited to this case. For example, the display device 10 may also be a display device of a type other than a light emitting display device. Embodiments in which the display device 10 is an organic light emitting display device are disclosed below. However, the display device 10 according to embodiments is not limited to an organic light emitting display device, and technical features of the embodiments to be described herein may also be applicable to other types of display devices.

The display device 10 may further include additional elements. For example, the display device 10 may further include a timing controller electrically connected to the scan driver 1100 and the data driver 1200 and a power supply circuit electrically connected to the pixels PX, the scan driver 1100 and the data driver 1200.

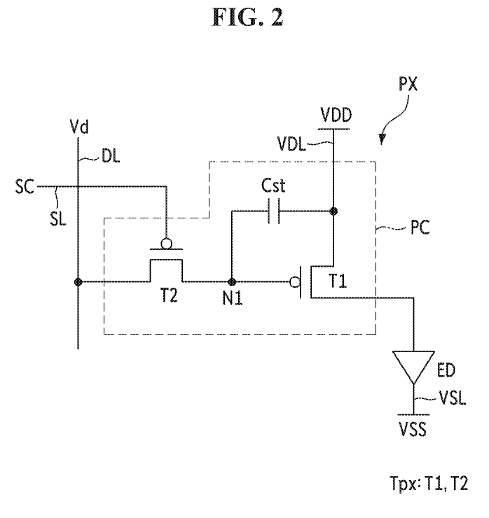

FIG. 2 is an equivalent circuit diagram of a pixel PX according to an embodiment. The pixel PX of FIG. 2 is disclosed as an example embodiment, and the structure or type of the pixel PX may vary depending on embodiments.

Referring to FIG. 2, the pixel PX may include a light emitting element ED and a pixel circuit PC connected to the light emitting element ED. The light emitting element ED is a light source of the pixel PX and may be, for example, an organic light emitting diode. The pixel circuit PC may supply a driving current corresponding to a data signal Vd to the light emitting element ED.

The pixel circuit PC may be connected to driving lines to which driving signals for driving the pixel PX are applied and power lines to which power supply voltages for driving the pixel PX are applied. For example, the pixel circuit PC may be connected to a scan line SL to which a scan signal SC is applied, a data line DL to which the data signal Vd is applied, a first power line VDL to which a first power supply voltage VDD (e.g., a high-potential pixel voltage) is applied, and a second power line VSL to which a second power supply voltage VSS (e.g., a low-potential pixel voltage) is applied.

The pixel circuit PC may include pixel transistors Tpx and a capacitor Cst. For example, the pixel circuit PC may include a first transistor T1, a second transistor T2, and the capacitor Cst.

The structure of the pixel circuit PC or the type and number of circuit elements constituting the pixel circuit PC may vary depending on embodiments. For example, the pixel circuit PC may further include at least one other pixel transistor and/or at least one other capacitor. In some aspects, although FIG. 2 illustrates an embodiment in which all of the pixel transistors Tpx are p-type transistors, embodiments are not limited to this case. For example, at least one pixel transistor Tpx may be formed as an n-type transistor.

The pixel circuit PC may supply a driving current to the light emitting element ED in response to driving signals supplied from the scan driver 1100 and the data driver 1200. For example, the pixel circuit PC may supply a driving current to the light emitting element ED in response to the scan signal SC supplied from the scan driver 1100 through the scan line SL and the data signal Vd supplied from the data driver 1200 through the data line DL.

The first transistor T1 may be a driving transistor that controls the driving current of the pixel PX in response to the voltage of a first node N1. The first transistor T1 may include a gate electrode connected to the first node N1, a first electrode connected to the first power line VDL, and a second electrode connected to the light emitting element ED. The first transistor T1 may control the driving current flowing to the light emitting element ED in response to the data signal Vd transmitted to the first node N1.

The second transistor T2 may be a switching transistor that is turned on in response to the scan signal SC. The second transistor T2 may include a gate electrode connected to the scan line SL, a first electrode connected to the data line DL, and a second electrode connected to the first node N1. The second transistor T2 may be turned on by the scan signal SC of a gate-on voltage transmitted to the scan line SL to connect the data line DL and the first node N1. Accordingly, the data signal Vd applied to the data line DL may be transmitted to the first node N1.

Depending on the type (e.g., a p-type or n-type transistor) and/or operating conditions of each of the first transistor T1 and the second transistor T2, the first electrode of each of the first transistor T1 and the second transistor T2 may be a source electrode or a drain electrode, and the second electrode may be a different electrode from the first electrode. In an example in which the first electrode of the first transistor T1 is a source electrode, the second electrode of the first transistor T1 may be a drain electrode.

The capacitor Cst may be a storage capacitor of the pixel PX and may store a voltage corresponding to the data signal Vd (e.g., data voltage). The capacitor Cst may be connected between the gate electrode and the first electrode of the first transistor T1. For example, the capacitor Cst may be connected between the first node N1 and the first power line VDL. In an embodiment, the first transistor T1 may be an n-type transistor, and the capacitor Cst may be connected between the gate electrode and the second electrode of the first transistor T1.

The light emitting element ED may be connected between the pixel circuit PC and the second power line VSL. The light emitting element ED may include a first electrode (e.g., an anode or a pixel electrode), a second electrode (e.g., a cathode or a counter electrode) facing the first electrode, and a light emitting layer (e.g., an organic light emitting layer) located between the first electrode and the second electrode. The first electrode of the light emitting element ED may be connected to the pixel circuit PC. The second electrode of the light emitting element ED may be connected to the second power line VSL. In an embodiment, the second electrode of the light emitting element ED may be a common electrode shared by a plurality of pixels PX. The light emitting element ED may emit light with a luminance corresponding to the driving current during a period in which the driving current is supplied from the pixel circuit PC.

The light emitting element ED may emit light of a specific color. For example, the light emitting element ED of each pixel PX may emit red, green or blue light or may emit red, green, blue or white light.

In an embodiment, the pixels PX of the display area DA may include first pixels emitting light of a first color, second pixels emitting light of a second color, and third pixels emitting light of a third color. A first pixel, a second pixel, and a third pixel adjacent to each other may form one unit pixel.

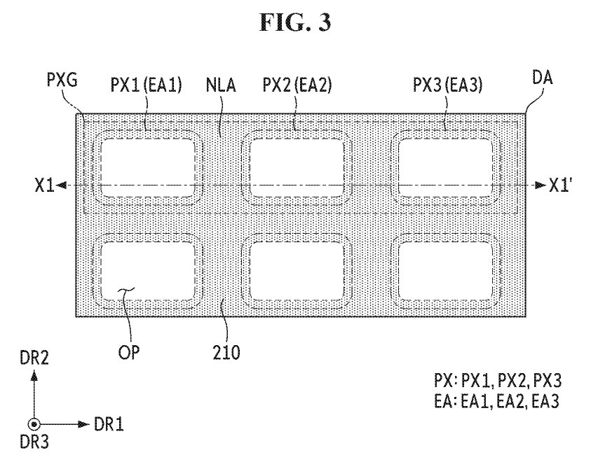

FIG. 3 is a plan view illustrating the schematic arrangement of a plurality of pixels PX in the display area DA of FIG. 1.

Referring to FIG. 3, the display area DA included in the display device 10 of the embodiment may include emission areas EA and a non-emission area NLA. The emission areas EA may be areas from which light is emitted, and the non-emission area NLA may entirely surround the emission areas EA.

The display device 10 of the embodiment may include a plurality of pixels PX in a portion overlapping the display area DA. The pixels PX may include first pixels PX1, second pixels PX2, and third pixels PX3. The first pixels PX1, the second pixels PX2 and the third pixels PX3 may overlap the emission areas EA, respectively, and may be spaced apart from each other by the non-emission area NLA. The non-emission area NLA may be located between the first pixels PX1, the second pixels PX2, and the third pixels PX3.

In some aspects, the emission areas EA of the display area DA may include first emission areas EA1 emitting light of a first color, second emission areas EA2 emitting light of a second color, and third emission areas EA3 emitting light of a third color. The first emission areas EA1, the second emission areas EA2, and the third emission areas EA3 may be adjacent to each other but may be spaced apart from each other by the non-emission area NLA. The non-emission area NLA may be located between the first emission areas EA1, the second emission areas EA2, and the third emission areas EA3.

The non-emission area NLA may help prevent the color mixing of light emitted from the first emission areas EA1 overlapping the first pixels PX1, light emitted from the second emission areas EA2 overlapping the second pixels PX2, and light emitted from the third emission areas EA3 overlapping the third pixels PX3.

An emission area EA overlapping at least one first pixel PX1, an emission area EA overlapping at least one second pixel PX2, and an emission area EA overlapping at least one third pixel PX3 may form a pixel group PXG. The pixel group PXG may be a smallest unit that emits white light. The type and/or number of emission areas EA constituting the pixel group PXG may vary depending on embodiments.

A pixel defining layer 210 may be located in a portion overlapping the non-emission area NLA in a plan view. The pixel defining layer 210 may define openings OP in a plan view, and the openings OP may be located in portions overlapping the emission areas EA. The pixel defining layer 210 may entirely surround the emission areas EA.

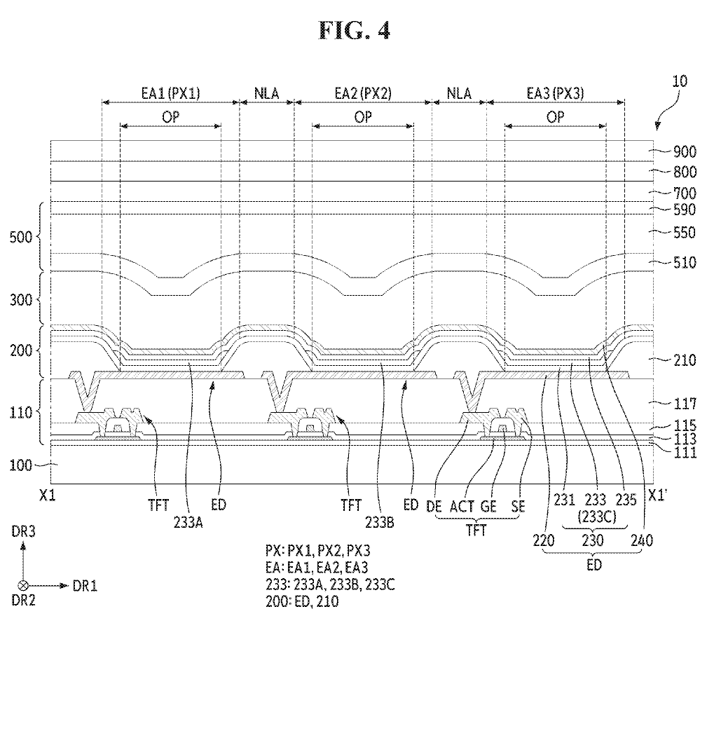

FIG. 4 is a schematic cross-sectional view of the display device 10 according to the embodiment, taken along line X1-X1’ of FIG. 3.

Referring to FIG. 4, the display device 10 may include the substrate 100, a pixel circuit layer 110, a light emitting element layer 200, a capping layer 300, an encapsulation layer 500, a polarizing member 700, a color control member 800, and a cover window 900. In an embodiment, the pixel circuit layer 110, the light emitting element layer 200, the capping layer 300, the encapsulation layer 500, the polarizing member 700, the color control member 800, and the cover window 900 may be sequentially located on the substrate 100 along the third direction DR3.

The substrate 100 may be a lower substrate of the display device 10. The substrate 100 may include a single layer or multiple layers and may have rigid or flexible characteristics. In an embodiment, the substrate 100 may be a substrate that includes an insulating material such as glass and has rigid characteristics. In this case, the substrate 100 cannot be bent. Alternatively, the substrate 100 may be a flexible substrate that includes polyimide or other insulating materials and can be bent, folded, rolled, or the like. In this case, the substrate 100 can be bent. However, embodiments are not limited to these cases, and the type, structure and/or material of the substrate 100 may vary depending on embodiments.

The pixel circuit layer 110 (e.g., a thin-film transistor layer) may be located on the substrate 100. The substrate 100 and the pixel circuit layer 110 may form a backplane layer of the display device 10.

The pixel circuit layer 110 may include circuit elements (e.g., the pixel transistors Tpx and the capacitor Cst of FIG. 2) that constitute the pixel circuit PC of each pixel PX and lines (e.g., the scan line SL, the data line DL, the first power line VDL and the second power line VSL of FIG. 2). In an embodiment, the pixel circuit layer 110 may further include circuit elements of the scan driver 1100.

FIG. 4 illustrates one thin-film transistor TFT as an example of the circuit elements that may be placed in the pixel circuit layer 110 in each pixel PX. Each thin-film transistor TFT of FIG. 4 may be one of the pixel transistors Tpx provided in the pixel circuit PC of a corresponding pixel PX. For example, each thin-film transistor TFT of FIG. 4 may be the first transistor T1 of FIG. 2.

The pixel circuit layer 110 of an embodiment may include a buffer layer 111, the thin-film transistors TFT, a gate insulating layer 113, an interlayer insulating layer 115, and a via layer 117.

The buffer layer 111 may be located on the substrate 100. The buffer layer 111 may include an inorganic insulating material and may include a single layer or multiple layers. The buffer layer 111 may include an inorganic insulating material, for example, may include at least any one of silicon oxide, silicon nitride, silicon oxynitride, silicon carbon nitride, titanium oxide, and aluminum oxide.

The thin-film transistors TFT may be located on the buffer layer 111. Each of the thin-film transistors TFT of an embodiment may include an active layer ACT, a gate electrode GE, a source electrode SE, and a drain electrode DE.

In an embodiment, each of the thin-film transistors TFT may omit the source electrode SE and/or the drain electrode DE, and a source region and/or a drain region of the active layer ACT may be connected to other circuit elements, conductive patterns, or lines to function as the source electrode and/or the drain electrode of the thin-film transistor TFT, respectively.

The active layer ACT may be located on the buffer layer 111. The active layer ACT may include a channel region overlapping the gate electrode GE and a source region and a drain region located on opposite sides of the channel region in the first direction DR1. The source region and the drain region may be conductive regions formed to have higher conductivity than the channel region by doping or other methods. The source region of the active layer ACT may be connected to the source electrode SE, and the drain region of the active layer ACT may be connected to the drain electrode DE.

The active layer ACT may include a semiconductor material. For example, the active layer ACT may include polysilicon, amorphous silicon, an oxide semiconductor, or other semiconductor materials.

The gate insulating layer 113 may cover the active layer ACT. The gate insulating layer 113 may insulate the active layer ACT from the gate electrode GE. The gate insulating layer 113 may include an inorganic insulating material, for example, may include at least any one of silicon oxide, silicon nitride, silicon oxynitride, silicon carbon nitride, titanium oxide, and aluminum oxide.

The gate electrode GE may be located on the gate insulating layer 113. The gate electrode GE may overlap the active layer ACT in the third direction DR3. The gate electrode GE may include a conductive material and may include a single layer or multiple layers.

For example, the gate electrode GE may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg) and other metals, an alloy thereof, or other conductive materials.

The interlayer insulating layer 115 may cover the gate electrode GE. The interlayer insulating layer 115 may include an inorganic insulating material, for example, may include at least any one of silicon oxide, silicon nitride, silicon oxynitride, silicon carbon nitride, titanium oxide, and aluminum oxide.

The source electrode SE and the drain electrode DE may be located on the interlayer insulating layer 115. Each of the source electrode SE and the drain electrode DE may include a conductive material and may include a single layer or multiple layers. In an example in which the source electrode SE and the drain electrode DE are located in the same layer, the source electrode SE and the drain electrode DE may be formed simultaneously using the same conductive material. Examples of the conductive material are omitted.

Each of the source electrode SE and the drain electrode DE may be connected to the active layer ACT through a contact hole penetrating the gate insulating layer 113 and the interlayer insulating layer 115.

The drain electrode DE of an embodiment may be connected to a light emitting element ED through a contact hole penetrating the via layer 117. Accordingly, the light emitting element ED may be electrically connected to the active layer ACT of a thin-film transistor TFT through the drain electrode DE. However, embodiments are not limited to this case, and for a case in which the thin-film transistor TFT is an n-type transistor, the source electrode SE of the thin-film transistor TFT may be connected to the light emitting element ED.

The via layer 117 may be located on the source electrode SE and the drain electrode DE. The via layer 117 may planarize the structures under the via layer 117.

The via layer 117 may include an organic material and may include a single layer or multiple layers. For example, the via layer 117 may include acrylic resin, epoxy resin, polyamide resin, polyimide resin, benzocyclobutene (BCB), hexamethyldisiloxane (HMDSO), or other organic materials.

The light emitting element layer 200 may be located on the pixel circuit layer 110. The light emitting element layer 200 may include light emitting elements ED and the pixel defining layer 210. In an embodiment, light emitting elements ED respectively included in a first pixel PX1, a second pixel PX2, and a third pixel PX3 may emit light of different wavelengths. For example, a light emitting element ED of the first pixel PX1 may emit light of a first color (e.g., red light), a light emitting element ED of the second pixel PX2 may emit light of a second color (e.g., green light), and a light emitting element ED of the third pixel PX3 may emit light of a third color (e.g., blue light).

Each of the light emitting elements ED may include a first electrode 220, an intermediate layer 230, and a second electrode 240 located sequentially.

The first electrode 220 may be located on the via layer 117 in a portion overlapping each emission area EA where the first pixel PX1, the second pixel PX2, or the third pixel PX3 is located. The first electrodes 220 included in the first pixel PX1, the second pixel PX2 and the third pixel PX3, respectively, may be spaced apart from each other by the pixel defining layer 210. The pixel defining layer 210 may be located between the first electrodes 220.

In an embodiment, the first electrode 220 may be a reflective electrode. For example, the first electrode 220 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof.

In an embodiment, the first electrode 220 may further include a transparent or translucent electrode layer located on and/or under the reflective layer. In an embodiment, the transparent or translucent electrode layer of the first electrode 220 may include at least one material selected from indium-tin oxide (ITO), indium-zinc oxide (IZO), zinc oxide (ZnO), indium oxide (InO or In₂O₃), indium-gallium oxide (IGO), and aluminum-zinc oxide (AZO). For example, the first electrode 220 may be, but is not limited to, a triple layer including an ITO layer, an Ag layer, and an ITO layer.

The pixel defining layer 210 may be located on the first electrodes 220 in a portion overlapping the non-emission area NLA. The pixel defining layer 210 may define openings OP and expose the first electrodes 220 in portions overlapping the openings OP. The pixel defining layer 210 may cover edges of the first electrodes 220.

The pixel defining layer 210 may insulate the first electrodes 220 included in the first pixel PX1, the second pixel PX2, and the third pixel PX3, respectively.

The pixel defining layer 210 may include an organic insulating material or an inorganic insulating material. In an example in which the pixel defining layer 210 includes an organic material, the pixel defining layer 210 may include polyimide, polyamide, acrylic resin, benzocyclobutene, hexamethyldisiloxane (HMDSO), or phenolic resin. In an example in which the pixel defining layer 210 includes an inorganic material, the pixel defining layer 210 may include silicon oxide, silicon nitride, silicon oxynitride, silicon carbon nitride, titanium oxide, and/or aluminum oxide.

The intermediate layer 230 may be located on the first electrodes 220 and the pixel defining layer 210. The intermediate layer 230 may include a first functional layer 231, light emitting layers 233, and a second functional layer 235.

The first functional layer 231 may include at least one of a hole transport layer and a hole injection layer. For example, the first functional layer 231 may include a hole transport layer or may include a hole transport layer and a hole injection layer. In an embodiment, at least one layer that forms the first functional layer 231 may be a common layer located over the entire display area DA.

The light emitting layers 233 may be located in the portions overlapping the emission areas EA. The light emitting layers 232 may include a fluorescent or phosphorescent material that can emit light of a specific color. The light emitting layers 233 may include a low-molecular organic material or a high-molecular organic material.

In an embodiment, the light emitting layers 233 may include a first light emitting layer 233A overlapping a first emission area EA1, a second light emitting layer 233B overlapping a second emission area EA2, and a third light emitting layer 233C overlapping a third emission area EA3. The first light emitting layer 233A included in the light emitting element ED of the first pixel PX1 may be a red light emitting layer that emits red light, the second light emitting layer 233B included in the light emitting element ED of the second pixel PX2 may be a green light emitting layer that emits green light, and the third light emitting layer 233C included in the light emitting element ED of the third pixel PX3 may be a blue light emitting layer that emits blue light.

The second functional layer 235 may include at least one of an electron transport layer and an electron injection layer. For example, the second functional layer 235 may include an electron transport layer or may include an electron transport layer and an electron injection layer. In an embodiment, at least one layer that forms the second functional layer 235 may be a common layer located over the entire display area DA.

The second electrode 240 may be located on the intermediate layer 230. In an embodiment, the second electrode 240 may be a common layer located over the entire display area DA. In other words, the second electrode 240 may be a common electrode.

In an embodiment, the second electrode 240 may be a transparent electrode or a translucent electrode. For example, the second electrode 240 may include a transparent conductive layer or a translucent conductive layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In an embodiment, the second electrode 240 may include, but is not limited to, silver (Ag), magnesium (Mg), or an alloy of silver (Ag) and magnesium (Mg). In an embodiment, the second electrode 240 may be, but is not limited to, a multilayer that further includes a conductive layer overlapping the transparent conductive layer or the translucent conductive layer and including a transparent conductive oxide (TCO) such as indium-tin oxide (ITO), indium-zinc oxide (IZO), zinc oxide (ZnO), or indium oxide (InO or In₂O₃).

The capping layer 300 may be located on the light emitting element layer 200. The capping layer 300 may assist in efficiently emitting light generated from the light emitting elements ED toward the outside. The capping layer 300 may cover the entire second electrode 240 in the portions overlapping the emission areas EA and the non-emission area NLA.

The capping layer 300 may include a single layer or multiple layers. In an example in which the capping layer 300 is a multilayer, the capping layer 300 may include at least three multilayers sequentially stacked on the second electrode 240. The at least three layers may have different thicknesses and refractive indices. Embodiments related to the structure of the capping layer 300 will be described later.

The encapsulation layer 500 may be located on the capping layer 300. The encapsulation layer 500 may reduce or prevent the penetration of moisture or oxygen into the light emitting element layer 200 or the like and may alleviate electrical and/or physical impact on the pixel circuit layer 110, the light emitting element layer 200, or the like.

The encapsulation layer 500 may be formed as a stacked structure of an organic layer and an inorganic layer. For example, the encapsulation layer 500 may include a first encapsulation layer 510 located on the capping layer 300, a second encapsulation layer 550 located on the first encapsulation layer 510, and a third encapsulation layer 590 located on the second encapsulation layer 550.

The first encapsulation layer 510 and the third encapsulation layer 590 may serve to prevent the penetration of moisture or oxygen and may include an inorganic insulating material. For example, the first encapsulation layer 510 and the third encapsulation layer 590 may include silicon oxide, silicon nitride, silicon oxynitride, silicon carbon nitride, titanium oxide, and/or aluminum oxide. However, embodiments are not limited to this example, and all inorganic insulating materials commonly used in the encapsulation layer 500 may be included.

In an embodiment, the first encapsulation layer 510 and the third encapsulation layer 590 may be formed by a chemical vapor deposition (CVD) process in a process of manufacturing the display device 10.

The second encapsulation layer 550 may planarize a structure under the second encapsulation layer 550 and alleviate impact applied to the structure. The second encapsulation layer 550 may include an organic material. For example, the second encapsulation layer 550 may include an organic material such as silicone resin, silicone acrylic resin, epoxy resin, or acrylic resin. However, embodiments are not limited to this example, and all organic materials commonly used in the encapsulation layer 500 may be included.

In an embodiment, the second encapsulation layer 550 may be formed by applying monomers having flowability and then curing the monomer layer using heat or ultraviolet light. Alternatively, the second encapsulation layer 550 may be formed by applying a polymer-based material described herein.

The polarizing member 700 may be located on the encapsulation layer 500. The polarizing member 700 may be a structure for preventing a decrease in the visibility of an image displayed by the display device 10 due to reflection of external light from the display device 10.

The polarizing member 700 may be attached onto the encapsulation layer 500 by a transparent adhesive member such as a pressure sensitive adhesive (PSA), an optically clear adhesive (OCA), or an optically clear resin (OCR).

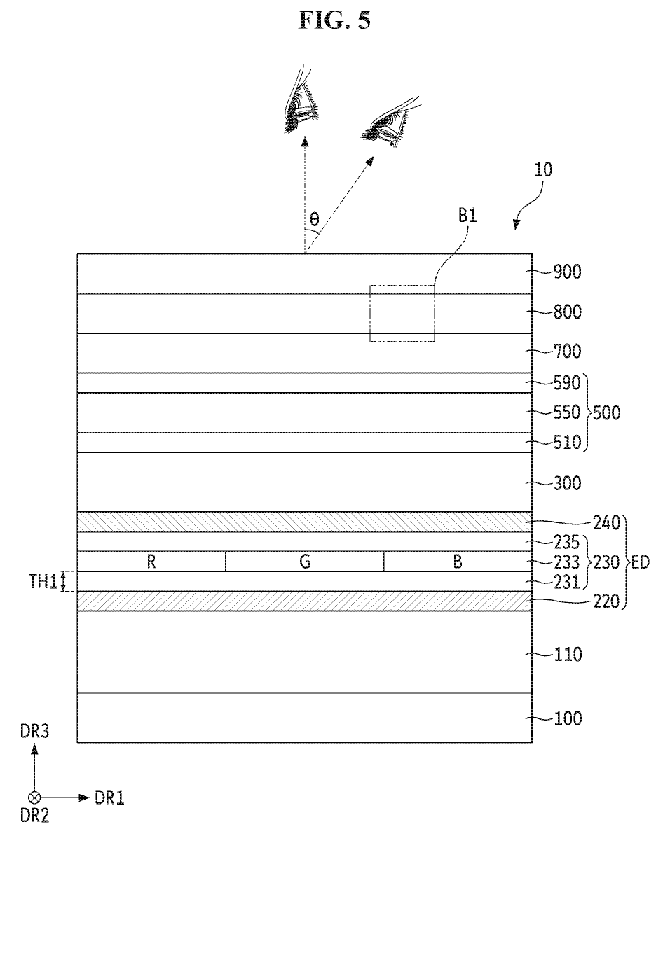

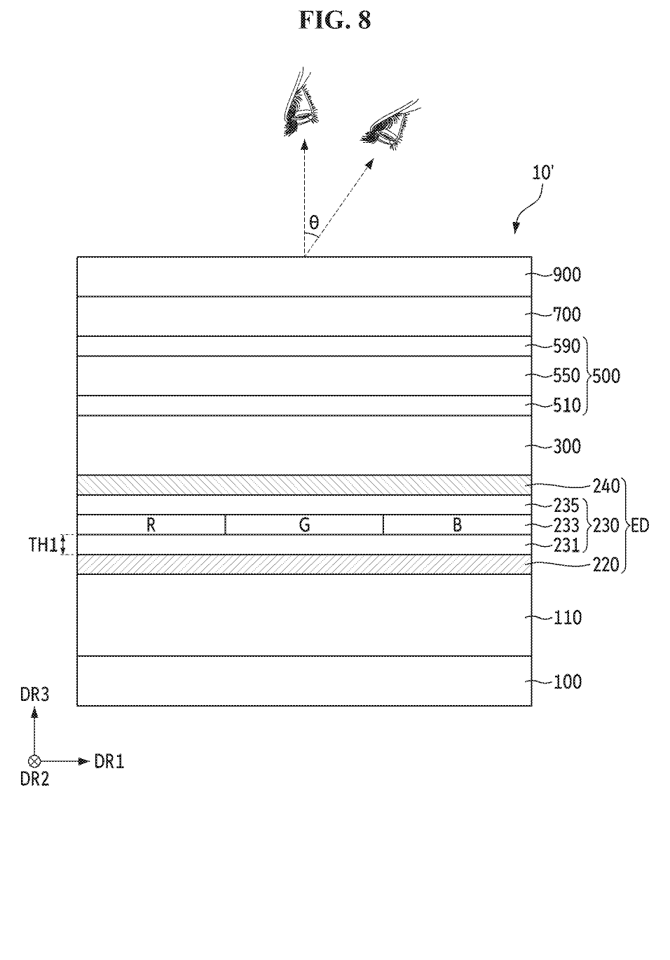

The color control member 800 may be located on the polarizing member 700. The color control member 800 may adjust a viewing angle color shift (VACS) phenomenon that occurs when the display device 10 is viewed from a lateral direction oblique to a direction (e.g., the third direction DR3) perpendicular to the substrate 100. The VACS may be measured by observing the display device 10 at angles of 0°, 30°, 45°, and 60° (e.g., θ in FIGS. 5 and 8 to be described later) with respect to the third direction DR3 perpendicular to the substrate 100. For example, the VACS may be determined by measuring rates of change in color coordinates measured at angles of 30°, 45°, and 60° based on color coordinates measured at 0° with respect to the third direction DR3 perpendicular to the substrate 100.

The color control member 800 may have different light transmittances for light traveling in a thickness direction (e.g., the third direction DR3) of the color control member 800 and in a direction (e.g., the second direction DR2 and the first direction DR1) intersecting the thickness direction of the color control member 800. In an embodiment, the light transmittance in the thickness direction of the color control member 800 may be higher than the light transmittance in the direction intersecting the thickness direction of the color control member 800. This will be described in detail later with reference to FIGS. 5-7.

The color control member 800 is located on a path along which light emitted from the light emitting elements ED travels. Therefore, the color control member 800 can correct the VACS of the display device 10 by reducing a luminance ratio of light of a specific wavelength range (e.g., blue light, green light, or red light) in the lateral direction oblique to the third direction DR3 and can reduce the dispersion of white angular dependency (WAD) according to a viewing angle. Accordingly, the display quality of the display device 10 can be improved.

The color control member 800 may be attached onto the polarizing member 700 by a transparent adhesive member such as a PSA, an OCA, or an OCR.

The cover window 900 may be located on the color control member 800. The cover window 900 may be placed on the color control member 800 to protect an upper portion of the display device 10. The cover window 900 may be an inorganic material such as glass or an organic material such as plastic or a polymer material.

The cover window 900 may be attached onto the color control member 800 by a transparent adhesive member such as an OCA film or an OCR.

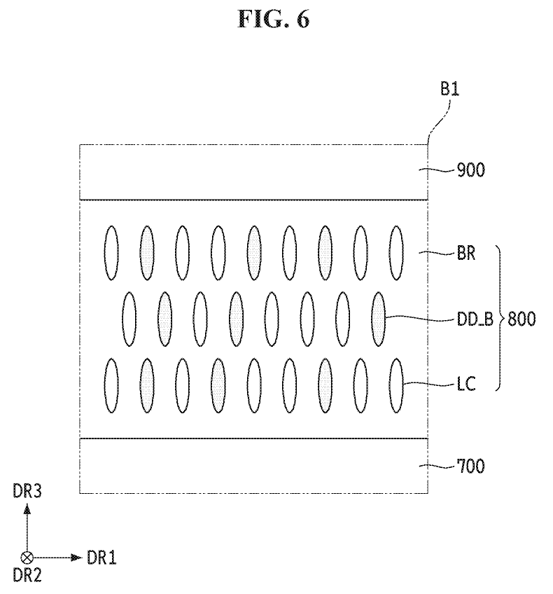

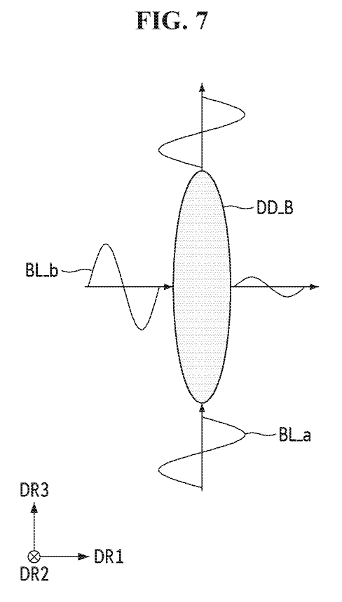

FIG. 5 is a schematic view of the display device 10 of FIG. 4. FIG. 6 is an enlarged cross-sectional view of portion B1 of FIG. 5. FIG. 7 is a schematic view of a first dichroic dye DD_B in FIG. 6.

The display device 10 illustrated in FIG. 5 includes the structure of the display device 10 illustrated in FIG. 4. Therefore, redundant descriptions of the substrate 100, the pixel circuit layer 110, the light emitting element layer 200, the capping layer 300, the encapsulation layer 500, the polarizing member 700 and the cover window 900 will be omitted below, and the detailed structure of the color control member 800 will be described.

Referring to FIGS. 5-7, the color control member 800 may include a base resin BR and first dichroic dyes DD_B and liquid crystals LC dispersed in the base resin BR.

The base resin BR may fix the alignment state of the first dichroic dyes DD_B and the liquid crystals LC. For example, the first dichroic dyes DD_B and the liquid crystals LC dispersed in the base resin BR may be aligned in a specific direction by heat, light, an electric field, or the like, and the aligned state of the first dichroic dyes DD_B and the liquid crystals LC may be maintained by the base resin BR as the base resin BR is cured. Examples of the base resin BR may include a thermosetting resin, a photocurable resin, and the like.

The first dichroic dyes DD_B may be dyes having a blue absorption wavelength and may have a different absorption rate depending on the direction in which blue light travels. For example, as illustrated in FIG. 7, a first dichroic dye DD_B may be aligned in the third direction DR3 to have a low absorption rate for a first component BL_a of blue light which travels in the third direction DR3 and a high absorption rate for a second component BL_b of the blue light which travels in the first direction DR1. In other words, the transmittance of the first component BL_a of the blue light transmitted in the third direction DR3 may be high, and the transmittance of the second component BL_b of the blue light transmitted in the first direction DR1 may be low. Therefore, a decrease in the intensity (amplitude) of the first component BL_a of the blue light transmitted through the first dichroic dye DD_B in the third direction DR3 may be small, and a decrease in the intensity (amplitude) of the second component BL_b of the blue light transmitted through the first dichroic dye DD_B in the first direction DR1 may be large. That is, the closer the direction of travel of the blue light passing through the first dichroic dye DD_B is to the first direction DR1 from the third direction DR3, the smaller the intensity (amplitude) of the blue light passing through the first dichroic dye DD_B aligned in the third direction DR3 may be.

In this way, the light transmittance in the thickness direction of the color control member 800 including the first dichroic dyes DD_B may be higher than the light transmittance in the direction (e.g., the first direction DR1 and the second direction DR2) intersecting the thickness direction of the color control member 800. Accordingly, the color control member 800 including the first dichroic dyes DD_B aligned in the third direction DR3 can reduce the luminance of blue light traveling in the lateral direction oblique to the third direction DR3. As a result, the VACS in a blue direction can be corrected to be close to the origin.

The liquid crystals LC may induce the alignment of the first dichroic dyes DD_B. In an example in which the liquid crystals LC are aligned in the third direction DR3, the first dichroic dyes DD_B may be induced to align in the same third direction DR3. Examples of the liquid crystals LC may include photo-reactive liquid crystals, thermo-reactive liquid crystals, electric field-reactive liquid crystals, magnetic field-reactive liquid crystals, and the like. In some aspects, in some cases, the liquid crystals LC may be photocurable reactive liquid crystals or thermo-curable reactive liquid crystals, and the base resin BR may be omitted. For example, the photo-curable reactive liquid crystals may include, within molecules, reaction sites that can cause a curing reaction by light irradiation in which light of a specific wavelength is provided. The thermo-curable reactive liquid crystals may include, within molecules, reaction sites that can cause a curing reaction by heat provided at a specific temperature. In an example in which the liquid crystals are aligned, the dichroic dyes may also be aligned and cured in the same direction as the liquid crystals.

FIG. 8 is a schematic view of a display device 10’ according to an embodiment.

The following description will focus on differences, and any redundant description will be omitted.

The display device 10’ of FIG. 8 may have the same structure as the display device 10 of FIG. 5 except that display device 10’ does not include a color control member 800.

Referring to FIGS. 5 and 8, a width of a first functional layer 231 of each of the display devices 10 and 10’ in the third direction DR3 may be defined as a thickness TH1 of the first functional layer 231. Each of the display devices 10 and 10’ may adjust the VACS by optimizing a resonance phenomenon, which may occur on the path of light emitted from light emitting elements ED, by adjusting the thickness TH1 of the first functional layer 231. For example, the first functional layer 231 may have a thickness TH1 of 1280 Å to 1480 Å.

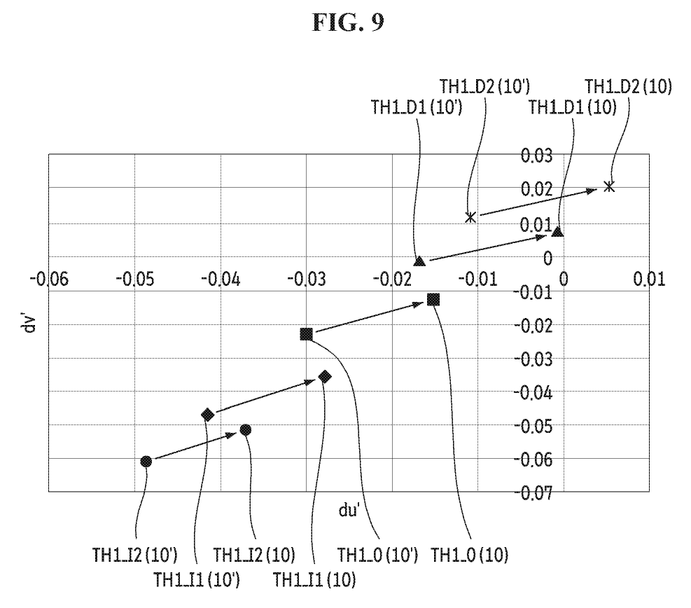

FIG. 9 illustrates the VACS of the display devices 10 and 10’ of FIGS. 5 and 8. FIG. 9 is the VACS for the rate of change (du’, dv’) in color coordinate values measured at an angle of 45° based on color coordinate values measured at 0°.

Referring to FIG. 9, the display device 10 of FIG. 5 and the display device 10’ of FIG. 8 can adjust the VACS by optimizing a resonance phenomenon, which may occur on the path of light emitted from the light emitting elements ED, by adjusting the thickness TH1 of the first functional layer 231.

According to FIG. 9, it can be seen that VACS values at a second thickness TH1_I1 of the first functional layer 231 greater than a first thickness TH1_0 of the first functional layer 231 and a third thickness TH1_I2 of the first functional layer 231 greater than the second thickness TH1_I1 of the first functional layer 231 change from a VACS value at the first thickness TH1_0 of the first functional layer 231, and VACS values at a fourth thickness TH1_D1 of the first functional layer 231 smaller than the first thickness TH1_0 of the first functional layer 231 and a fifth thickness TH1_D2 of the first functional layer 231 smaller than the fourth thickness TH1_D1 of the first functional layer 231 change from the VACS value at the first thickness TH1_0 of the first functional layer 231. In some aspects, it can be seen that the VACS in the blue direction is improved in the display device 10 of FIG. 5 including the color control member 800 at the same thicknesses TH1_0, TH1_I1, TH1_I2, TH1_D1 and TH1_D2 of the first functional layer 231 as those of the display device 10’ of FIG. 8.

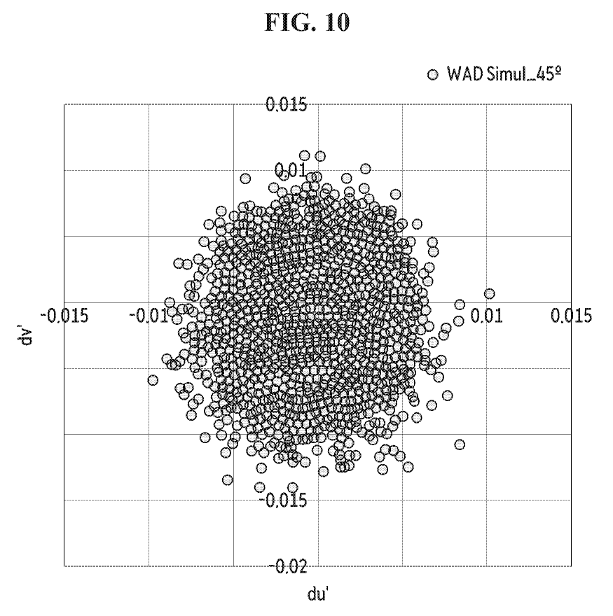

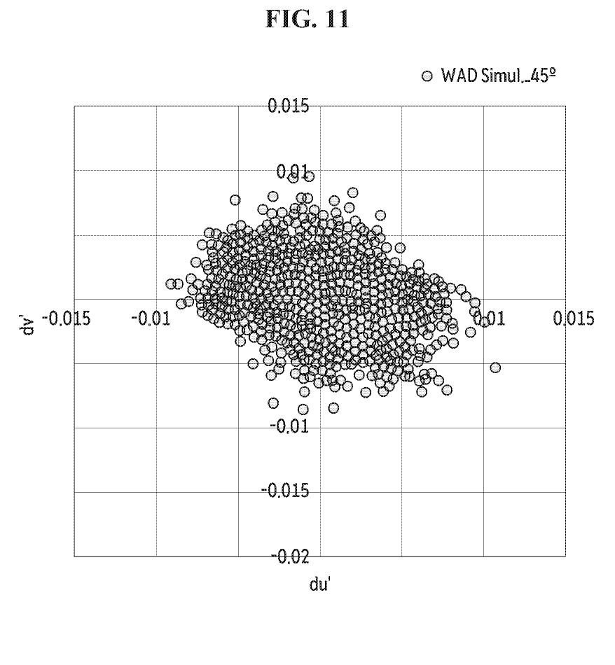

FIG. 10 illustrates the WAD of the display device 10’ of FIG. 8. FIG. 11 illustrates the WAD of the display device 10 of FIG. 5. FIGS. 10 and 11 are the WADs for the rate of change (du’, dv’) in color coordinate values measured at an angle of 45° based on color coordinate values measured at 0°.

Referring to FIGS. 10 and 11, it can be seen that the display device 10 of FIG. 5 has a reduced VACS dispersion compared with the display device 10’ of FIG. 8 because the display device 10 includes the color control member 800. In particular, it can be seen that the VACS dispersion in the blue direction is improved.

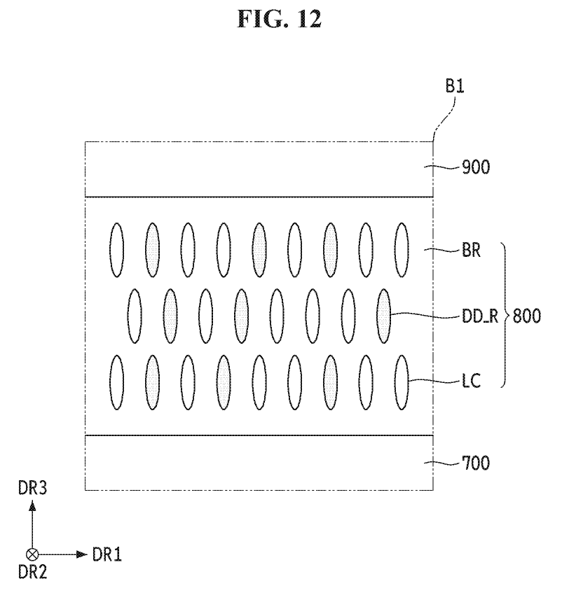

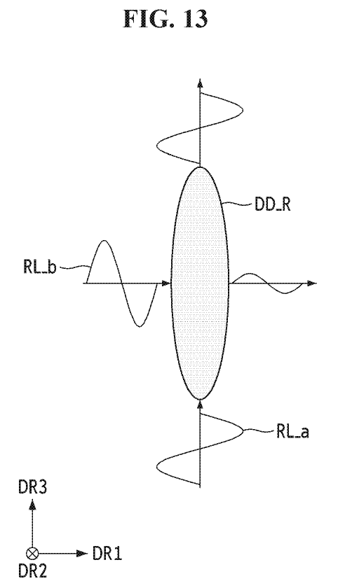

FIG. 12 is an enlarged cross-sectional view of portion B1 of FIG. 5 of a display device according to an embodiment. FIG. 13 is a schematic view of a second dichroic dye DD_R.

The following description will focus on differences, and any redundant description will be omitted.

Referring to FIGS. 12 and 13, a color control member 800 may be different from the color control member 800 of FIGS. 6 and 7 in that the color control member 800 of FIGS. 12 and 13 includes second dichroic dyes DD_R dispersed in a base resin BR instead of the first dichroic dyes DD_B, but may be the same as the color control member 800 of FIGS. 6 and 7 with respect to the base resin BR, liquid crystals LC and a structure including the base resin BR and the liquid crystals LC.

The second dichroic dyes DD_R may be dyes having a red absorption wavelength and may have a different absorption rate depending on the direction in which red light travels. For example, as illustrated in FIG. 13, a second dichroic dye DD_R may be aligned in the third direction DR3 to have a low absorption rate for a first component RL_a of red light which travels in the third direction DR3 and a high absorption rate for a second component RL_b of the red light which travels in the first direction DR1. In other words, the transmittance of the first component RL_a of the red light transmitted in the third direction DR3 may be high, and the transmittance of the second component RL_b of the red light transmitted in the first direction DR1 may be low. Therefore, a decrease in the intensity (amplitude) of the first component RL_a of the red light transmitted through the second dichroic dye DD_R in the third direction DR3 may be small, and a decrease in the intensity (amplitude) of the second component RL_b of the red light transmitted through the second dichroic dye DD_R in the first direction DR1 may be large. That is, the closer the direction of travel of the red light passing through the second dichroic dye DD_R is to the first direction DR1 from the third direction DR3, the smaller the intensity (amplitude) of the red light passing through the second dichroic dye DD_R aligned in the third direction DR3 may be.

In this way, the light transmittance in a thickness direction of the color control member 800 including the second dichroic dyes DD_R may be higher than the light transmittance in a direction (e.g., the first direction DR1 and the second direction DR2) intersecting the thickness direction of the color control member 800. Accordingly, the color control member 800 including the second dichroic dyes DD_R aligned in the third direction DR3 can reduce the luminance of red light traveling in a lateral direction oblique to the third direction DR3. As a result, the VACS in a red direction can be corrected to be close to the origin.

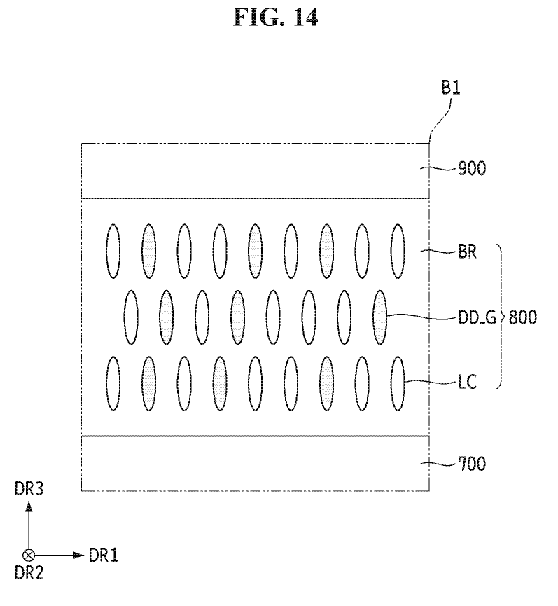

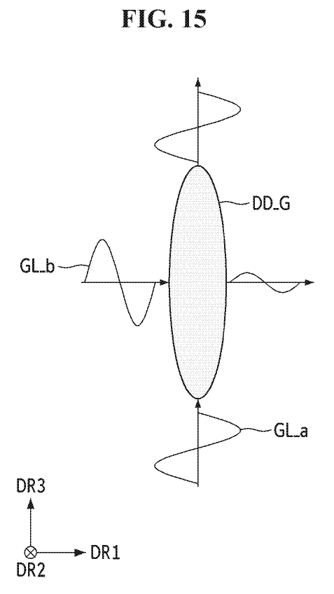

FIG. 14 is an enlarged cross-sectional view of portion B1 of FIG. 5 of a display device according to an embodiment. FIG. 15 is a schematic view of a third dichroic dye DD_G.

The following description will focus on differences, and any redundant description will be omitted.

Referring to FIGS. 14 and 15, a color control member 800 may be different from the color control member 800 of FIGS. 6 and 7 in that the color control member 800 of FIGS. 14 and 15 includes third dichroic dyes DD_B dispersed in a base resin BR instead of the first dichroic dyes DD_B, but may be the same as the color control member 800 of FIGS. 6 and 7 with respect to the base resin BR, liquid crystals LC and a structure including the base resin BR and the liquid crystals LC.

The third dichroic dyes DD_G may be dyes having a green absorption wavelength and may have a different absorption rate depending on the direction in which green light travels. For example, as illustrated in FIG. 15, a third dichroic dye DD_G may be aligned in the third direction DR3 to have a low absorption rate for a first component GL_a of green light which travels in the third direction DR3 and a high absorption rate for a second component GL_b of the green light which travels in the first direction DR1. In other words, the transmittance of the first component GL_a of the green light transmitted in the third direction DR3 may be high, and the transmittance of the second component GL_b of the green light transmitted in the first direction DR1 may be low. Therefore, a decrease in the intensity (amplitude) of the first component GL_a of the green light transmitted through the third dichroic dye DD_G in the third direction DR3 may be small, and a decrease in the intensity (amplitude) of the second component GL_b of the green light transmitted through the third dichroic dye DD_G in the first direction DR1 may be large. That is, the closer the direction of travel of the green light passing through the third dichroic dye DD_G is to the first direction DR1 from the third direction DR3, the smaller the intensity (amplitude) of the green light passing through the third dichroic dye DD_G aligned in the third direction DR3 may be.

In this way, the light transmittance in a thickness direction of the color control member 800 including the third dichroic dyes DD_G may be higher than the light transmittance in a direction (e.g., the first direction DR1 and the second direction DR2) intersecting the thickness direction of the color control member 800. Accordingly, the color control member 800 including the third dichroic dyes DD_G aligned in the third direction DR3 can reduce the luminance of green light traveling in a lateral direction oblique to the third direction DR3. As a result, the VACS in a green direction can be corrected to be close to the origin.

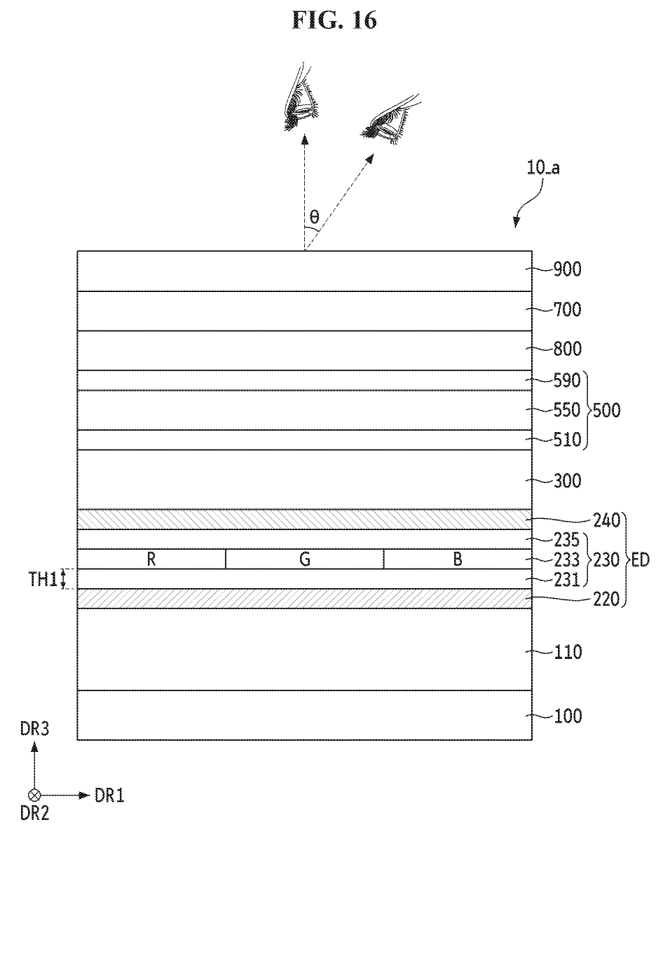

FIG. 16 is a schematic view of a display device according to an embodiment.

The following description will focus on differences, and any redundant description will be omitted.

Referring to FIG. 16, positions of a color control member 800 and a polarizing member 700 may be different from those in FIG. 5. For example, the color control member 800 may be located on an encapsulation layer 500, the polarizing member 700 may be located on the color control member 800, and a cover window 900 may be located on the polarizing member 700. The other structure of the display device may be the same as the structure of the display device 10 of FIG. 5.

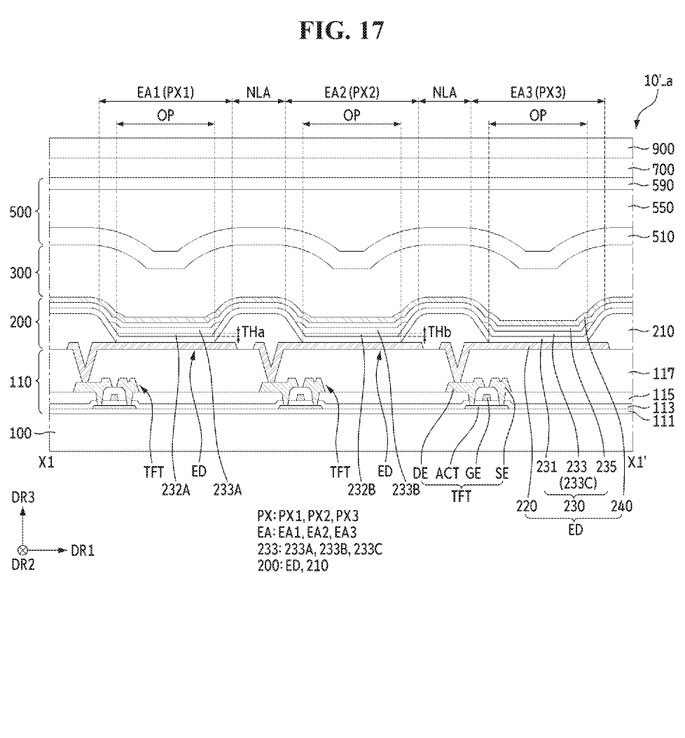

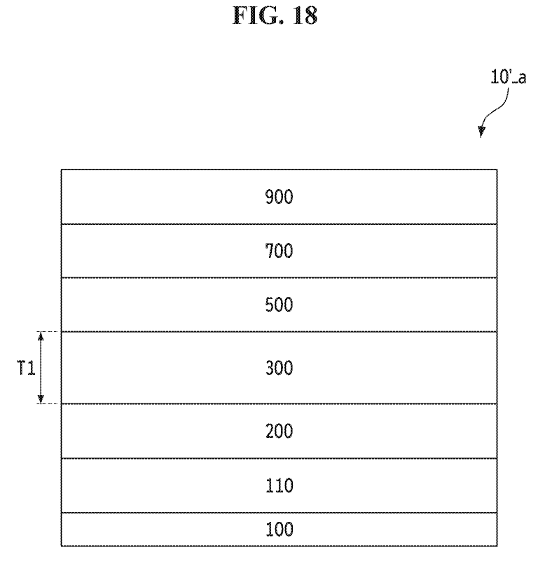

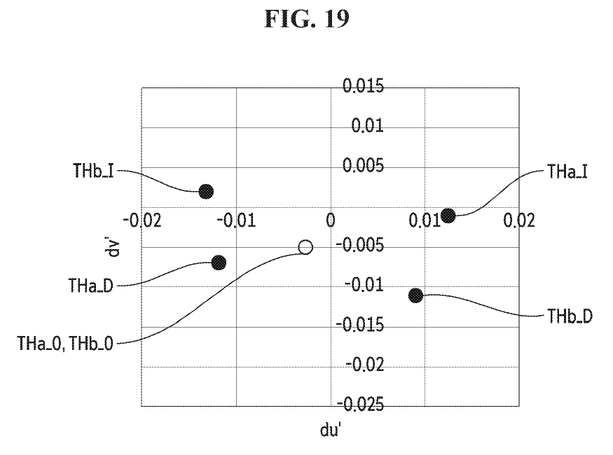

FIG. 17 is a cross-sectional view of a display device 10’_a according to an embodiment, taken along line X1-X1’ of FIG. 3. FIG. 18 is a schematic view of the display device 10’_a of FIG. 17. FIG. 19 illustrates the VACS of the display device 10’_a of FIGS. 17 and 18.

The following description will focus on differences, and any redundant description will be omitted.

First, referring to FIG. 17, compared with the display device 10 of FIG. 4, the display device 10’_a of FIG. 17 may be implemented without a color control member 800.

In some aspects, an intermediate layer 230 of light emitting elements ED of a first pixel PX1 and a second pixel PX2 of the display device 10’_a may further include a first sub-functional layer 232A located between a first functional layer 231 and a first light emitting layer 233A and overlapping a first emission area EA1 and a second sub-functional layer 232B located between the first functional layer 231 and a second light emitting layer 233B and overlapping a second emission area EA2.

The first sub-functional layer 232A may be located in a portion overlapping the emission area EA of the first pixel PX1. The second sub-functional layer 232B may be located in a portion overlapping the emission area EA of the second pixel PX2. The first sub-functional layer 232A and the second sub-functional layer 232B may include a hole transport layer.

A width of the first sub-functional layer 232A in the third direction DR3 may be defined as a thickness THa of the first sub-functional layer 232A, and a width of the second sub-functional layer 232B in the third direction DR3 may be defined as a thickness THb of the second sub-functional layer 232B. The display device 10’_a can adjust a VACS value by optimizing a resonance phenomenon, which may occur on the path of light emitted from the light emitting elements ED, by adjusting the thickness THa of the first sub-functional layer 232A and the thickness THb of the second sub-functional layer 232B.

In some embodiments, the thickness THa of the first sub-functional layer 232A and the thickness THb of the second sub-functional layer 232B may be different from each other. Specifically, the thickness THa of the first sub-functional layer 232A may be greater than the thickness THb of the second sub-functional layer 232B. For example, the first sub-functional layer 232A may have a thickness THa of 600 to 800 Å, and the second sub-functional layer 232B may have a thickness THb of 400 Å to 600 Å.

Alternatively, in some embodiments, the thickness THa of the first sub-functional layer 232A and the thickness THb of the second sub-functional layer 232B may be the same.

Next, referring to FIG. 18, a capping layer 300 included in the display device 10’_a may be formed as a single layer. A width of the capping layer 300 in the third direction DR3 may be defined as a thickness T1 of the capping layer 300. The capping layer 300 may have a certain thickness and refractive index range which maximizes the resonance phenomenon formed between a light emitting element layer 200 and an encapsulation layer 500. For example, the thickness T1 of the capping layer 300 may range from 600 Å to 900 Å, and the refractive index of capping layer 300 may range from 1.9 to 2.3.

Next, referring to FIG. 19, it can be seen that a VACS value of the display device 10’_a changes from a VACS value at a first thickness THa_0 of the first sub-functional layer 232A and a first thickness THb_0 of the second sub-functional layer 232B because the display device 10’_a has a second thickness THa_I of the first sub-functional layer 232A greater than the first thickness THa_0 of the first sub-functional layer 232A and a third thickness THa_D of the first sub-functional layer 232A smaller than the first thickness THa_0 of the first sub-functional layer 232A and has a second thickness THb_I of the second sub-functional layer 232B greater than the first thickness THb_0 of the second sub-functional layer 232B and a third thickness THb_D of the second sub-functional layer 232B smaller than the first thickness THb_0 of the second sub-functional layer 232B.

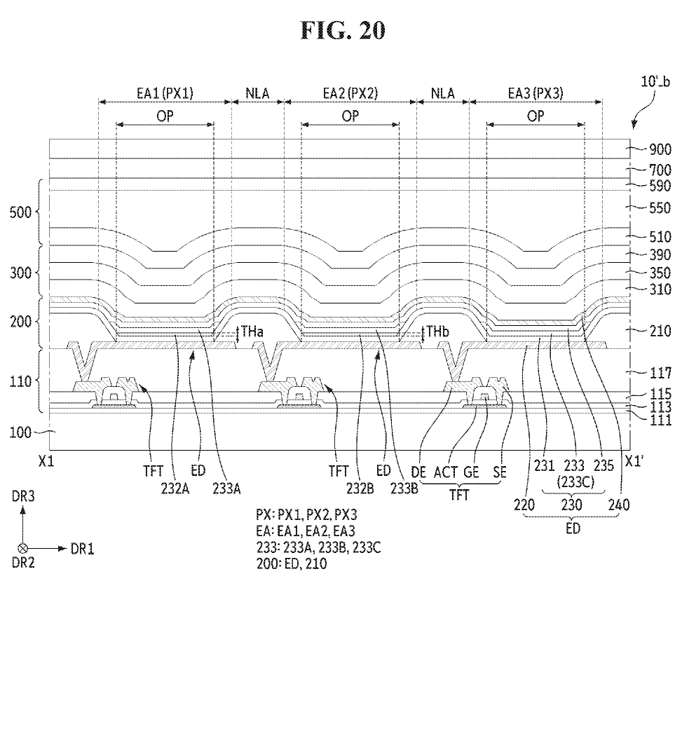

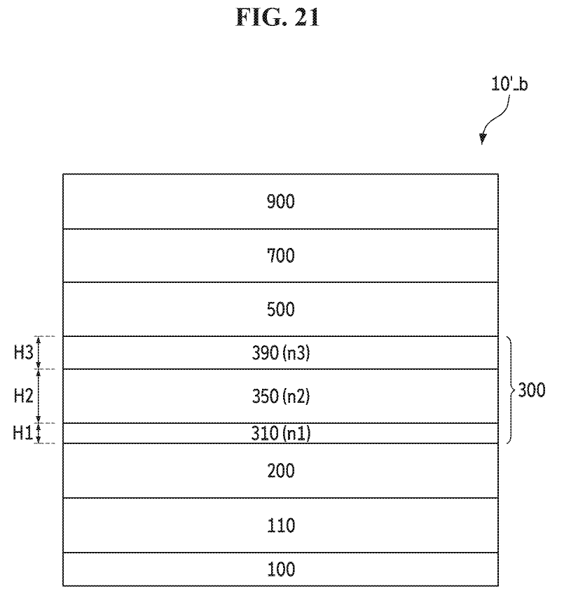

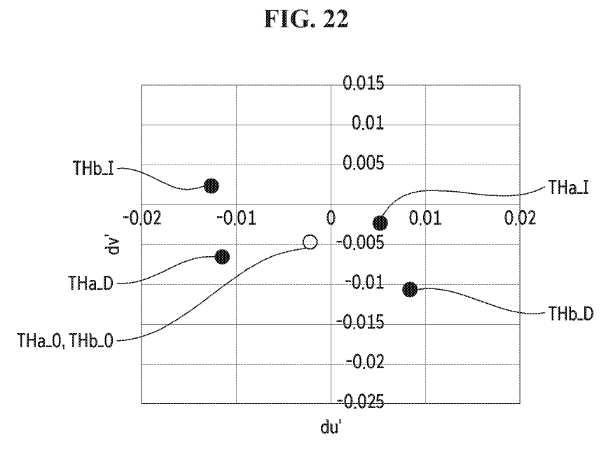

FIG. 20 is a cross-sectional view of a display device 10’_b according to an embodiment, taken along line X1-X1’ of FIG. 3. FIG. 21 is a schematic view of the display device 10’_b of FIG. 20. FIG. 22 illustrates the VACS of the display device 10’_b of FIGS. 20 and 21.

The following description will focus on differences, and any redundant description will be omitted.

First, referring to FIGS. 20 and 22, compared with the display device 10’_a of FIGS. 17 and 18, the display device 10’_b may have a capping layer 300 including a first capping layer 310 having a low refractive index characteristic, a second capping layer 350 having a high refractive index characteristic, and a third capping layer 390 having a low refractive index characteristic in order to maximize resonance formed between a light emitting element layer 200, the capping layer 300, and an encapsulation layer 500.

In the display device 10’_b, the first capping layer 310, the second capping layer 350, and the third capping layer 390 may be sequentially stacked on the light emitting element layer 200, and each of the first capping layer 310, the second capping layer 350 and the third capping layer 390 may be formed to have an optimized optical thickness and refractive index range supportive of reducing or preventing a VACS dispersion defect. Accordingly, a VACS dispersion defect of the display device 10’_b can be solved.

In some embodiments, refractive indices of the first capping layer 310, the second capping layer 350, and the third capping layer 390 may be different from each other. Specifically, the refractive indices of the first capping layer 310 and the third capping layer 390 may be lower than the refractive index of the second capping layer 350. Accordingly, the first capping layer 310 and the third capping layer 390 may be described as low refractive index layers, and the second capping layer 350 may be described as a high refractive index layer. For example, the first capping layer 310 may have a first refractive index n1, the second capping layer 350 may have a second refractive index n2, and the third capping layer 390 may have a third refractive index n3. The first refractive index n1 and the third refractive index n3 may each have a value of 1.5 to 1.8, and the second refractive index n2 may have a value of 1.9 to 2.3.

In some aspects, a width of the first capping layer 310 in the third direction DR3 may be defined as a thickness H1 of the first capping layer 310, a width of the second capping layer 350 in the third direction DR3 may be defined as a thickness H2 of the second capping layer 350, and a width of the third capping layer 390 in the third direction DR3 may be defined as a thickness H3 of the third capping layer 390. In some embodiments, the thickness H1 of the first capping layer 310, the thickness H2 of the second capping layer 350, and the thickness H3 of the third capping layer 390 may be different from each other. Specifically, the thickness H1 of the first capping layer 310 may be smaller than the thickness H3 of the third capping layer 390, and the thickness H3 of the third capping layer 390 may be smaller than the thickness H2 of the second capping layer 350. For example, the first capping layer 310 may have a thickness of 50 Å to 200 Å, the second capping layer 350 may have a thickness of 350 Å to 500 Å, and the third capping layer 390 may have a thickness of 200 Å to 300 Å.

Next, referring to FIG. 22, compared with FIG. 19, the display device 10’_b can improve VACS by including the first, second and third capping layers 310, 350 and 390 having different refractive indices and thicknesses. According to FIG. 22, it can be seen that, compared with FIG. 19, the VACS in the red and green directions is improved at a first thickness THa_0 of a first sub-functional layer, a first thickness THb_0 of a second sub-functional layer, a second thickness THa_I of the first sub-functional layer, a third thickness THa_D of the first sub-functional layer, a second thickness THb_I of the second sub-functional layer, and a third thickness THb_D of the second sub-functional layer.

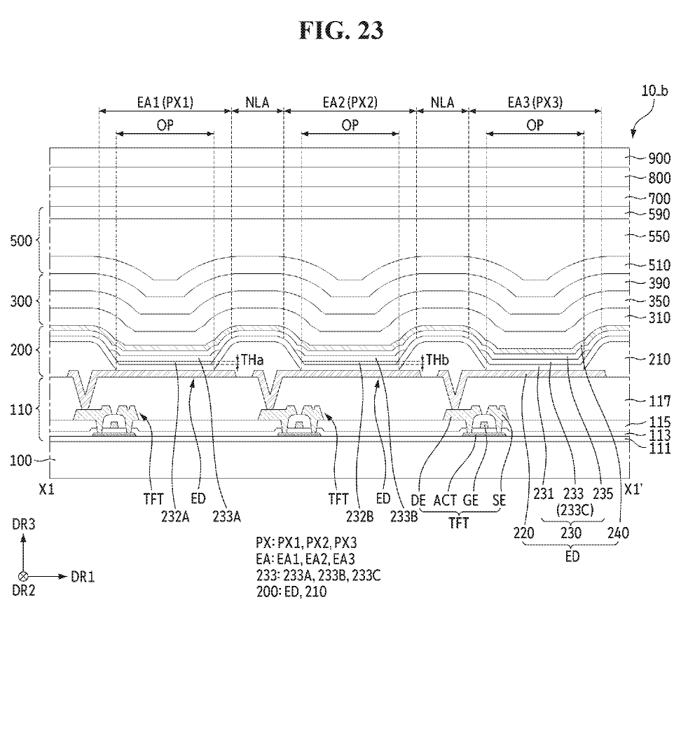

FIG. 23 is a cross-sectional view of a display device 10_baccording to an embodiment, taken along line X1-X1’ of FIG. 3.

The following description will focus on differences, and any redundant description will be omitted.

Referring to FIG. 23, compared with FIG. 20, the display device 10_b may further include a color control member 800 between a polarizing member 700 and a cover window 900.

The display device 10_b can improve VACS dispersion in the red, green, and blue directions by further including the color control member 800 in the display device 10’_b of FIG. 20. Therefore, the display quality of the display device 10_b can be improved.

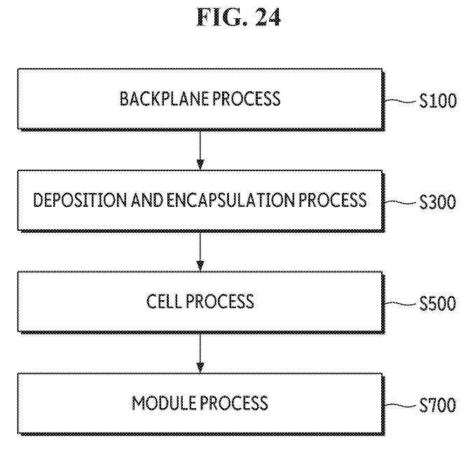

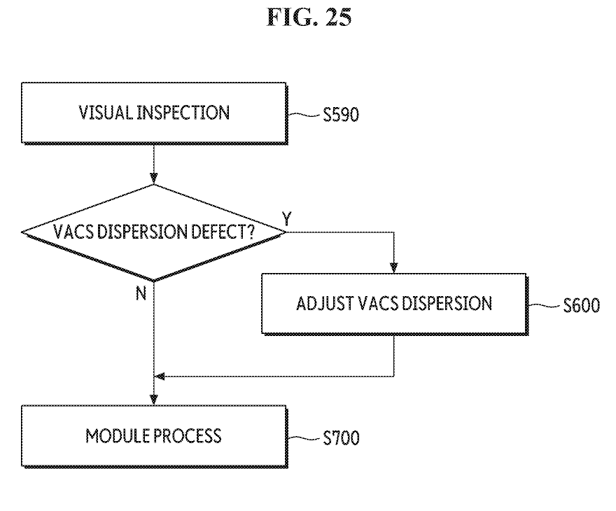

FIG. 24 is a flowchart schematically illustrating a method of manufacturing a display device according to various embodiments. FIG. 25 illustrates a VACS dispersion adjustment operation in the method of manufacturing a display device according to an embodiment of FIG. 24.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

First, referring to FIG. 24, the method of manufacturing the display device according to the embodiment sequentially includes performing a backplane process operation S100, a deposition and encapsulation process operation S300, a cell process operation S500, and a module process operation S700.

In the backplane process operation S100, a pixel circuit layer 110 may be formed on a substrate 100.

In the deposition and encapsulation process operation S300, a light emitting element layer 200, a capping layer 300, and an encapsulation layer 500 may be formed on the pixel circuit layer 110.

In the cell process operation S500, a protective film or the like may be additionally attached onto the encapsulation layer 500 as applicable or desired, a large-sized mother glass may be cut to an appropriate size according to the purpose of a final product, and then automatic visual inspection (AVI) (hereinafter, referred to as visual inspection) may be performed. The visual inspection operation is an operation for inspecting the image quality characteristics and defects of a target display panel. The target display panel may be inspected for VACS defects by applying an inspection signal to the target display panel.

In the module process operation S700, a polarizing member 700, a cover window 900, or the like may be attached.

Next, referring to FIG. 25, the method of manufacturing the display device may further include a VACS dispersion adjustment operation S600 between the visual inspection operation S590 of the cell process operation S500 and the module process operation S700. In some aspects, the method may include performing the VACS dispersion adjustment operation S600 based on determining the VACS dispersion of the display panel is defective(i.e., if the VACS dispersion as shown in FIGS. 10 and 11 deviates from the change rate (du’, dv’) of the color coordinate values within a preset specific range, it may be judged as defective.). In FIG. 23, the VACS dispersion adjustment operation S600 is performed between the visual inspection operation S590 of the cell process operation S500 and the module process operation S700. However, this is an example, and the VACS dispersion adjustment operation S600 may also be included in the module process operation S700. For example, the VACS dispersion adjustment operation S600 may be performed before or after a polarizing member forming operation of the module process operation S700.

A display device according to an embodiment can be applied to various electronic devices. An electronic device according to an embodiment includes the display device described herein and may further include modules or devices having additional functions, in addition to the display device.

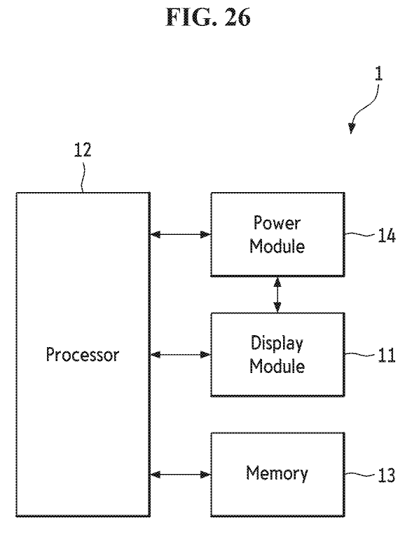

FIG. 26 is a block diagram of an electronic device 1 according to an embodiment.

Referring to FIG. 26, the electronic device 1 according to the embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information supportive of the operation of the processor 12 or the display module 11. In an example in which the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module. The power conversion module may generate power for the operation of the electronic device 1 by converting power supplied by the power supply module.

At least one of the elements of the electronic device 1 described herein may be included in a display device according to the above-described embodiments. In some aspects, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 1.

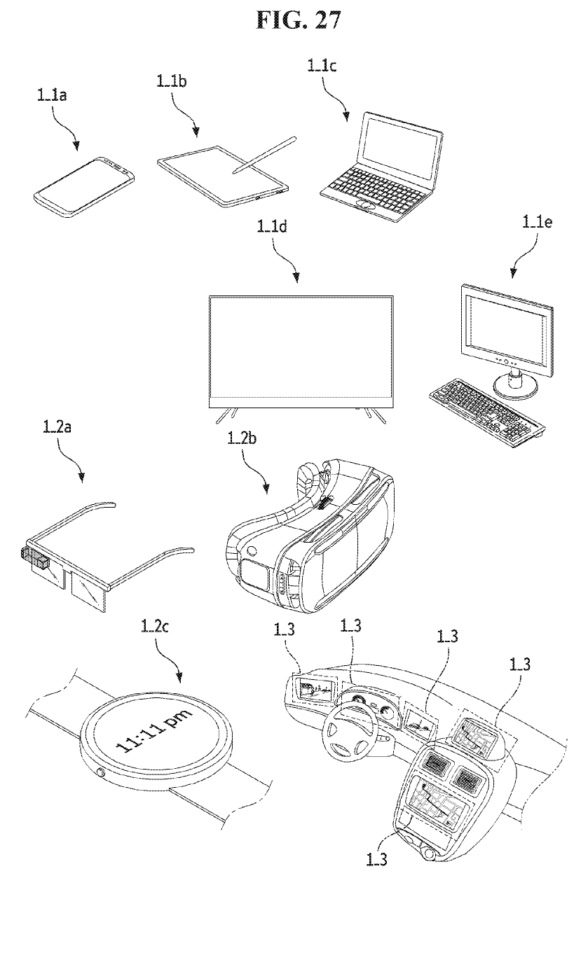

FIG. 27 is a schematic diagram of electronic devices according to various embodiments.

Referring to FIG. 27, various electronic devices to which display devices according to embodiments are applied may include image display electronic devices such as a smartphone 1_1a, a tablet PC 1_1b, a laptop 1_1c, a television 1_1d, and a desk monitor 1_1e. In some aspects, the various electronic devices to which the display devices according to the embodiments are applied may include wearable electronic devices including a display module, such as smart glasses 1_2a, a head-mounted display 1_2b and a smart watch 1_2c, and vehicle electronic devices 1_3 including a display module, such as a center information display (CID) and a room mirror display placed on an instrument cluster, center fascia and dashboard of a vehicle.

In concluding the detailed description, those skilled in the art will appreciate that many variations and modifications can be made to the example embodiments without substantially departing from the principles of the present invention. Therefore, the disclosed example embodiments of the present disclosure are used in a generic and descriptive sense and not for purposes of limitation.

What is claimed is:

1. A display device comprising:
a substrate comprising:
a non-emission area; and
a first emission area, a second emission area, and a third emission area adjacent to each other but spaced apart from each other by the non-emission area located between the first emission area, the second emission area, and the third emission area;
a light emitting element located on the substrate;
a capping layer located on the light emitting element;
an encapsulation layer located on the capping layer; and
a color control member located on the encapsulation layer,
wherein the light emitting element comprises:
a functional layer located on the substrate;
a first light emitting layer, a second light emitting layer, and a third light emitting layer located on the functional layer and overlapping the first emission area, the second emission area, and the third emission area, respectively,
wherein the functional layer has a thickness of 1280 Å to 1480 Å.

2. The display device of claim 1, wherein the light emitting element further comprises:
a first sub-functional layer located between the functional layer and the first light emitting layer and overlapping the first emission area; and
a second sub-functional layer located between the functional layer and the second light emitting layer and overlapping the second emission area.

3. The display device of claim 2, wherein a thickness of the first sub-functional layer and a thickness of the second sub-functional layer are different from each other.

4. The display device of claim 3, wherein the thickness of the first sub-functional layer is greater than the thickness of the second sub-functional layer.

5. The display device of claim 2, wherein:
the first sub-functional layer has a thickness of 600 Å to 800 Å, and
the second sub-functional layer has a thickness of 400 Å to 600 Å.

6. The display device of claim 2, wherein the capping layer has a refractive index of 1.9 to 2.3 and a thickness of 600 Å to 900 Å.

7. The display device of claim 2, wherein the capping layer comprises:
a first capping layer located on the light emitting element,
a second capping layer located on the first capping layer, and
a third capping layer located on the second capping layer,
wherein the first capping layer has a first refractive index, the second capping layer has a second refractive index, and the third capping layer has a third refractive index.

8. The display device of claim 7, wherein the first refractive index and the third refractive index are different from the second refractive index.

9. The display device of claim 8, wherein the first refractive index and the third refractive index are smaller than the second refractive index.

10. The display device of claim 7, wherein:
the first refractive index and the third refractive index have a value of 1.5 to 1.8, and
the second refractive index has a value of 1.9 to 2.3.

11. The display device of claim 7, wherein a thickness of the first capping layer, a thickness of the second capping layer, and a thickness of the third capping layer are different from each other.

12. The display device of claim 11, wherein:
the thickness of the first capping layer is smaller than the thickness of the third capping layer, and
the thickness of the third capping layer is smaller than the thickness of the second capping layer.

13. The display device of claim 7, wherein:
the first capping layer has a thickness of 50 Å to 200 Å,
the second capping layer has a thickness of 350 Å to 500 Å, and
the third capping layer has a thickness of 200 Å to 300 Å.

14. The display device of claim 1, wherein the color control member has a light transmittance for light traveling in a thickness direction of the color control member and a light transmittance for light traveling in a direction intersecting the thickness direction of the color control member.

15. The display device of claim 14, wherein the light transmittance in the thickness direction of the color control member is higher than the light transmittance in the direction intersecting the thickness direction of the color control member.

16. The display device of claim 15, wherein each of the light transmittances is the transmittance of light in a blue wavelength range.

17. The display device of claim 15, wherein each of the light transmittances is the transmittance of light in a green wavelength range.

18. The display device of claim 15, wherein each of the light transmittances is the transmittance of light in a red wavelength range.

19. A method of manufacturing a display device, the method comprising:
performing a deposition and encapsulation process operation which comprises forming a substrate, a light emitting element located on the substrate, a capping layer located on the light emitting element, and an encapsulation layer located on the capping layer;
performing a visual inspection operation which comprises measuring a viewing angle color shift of light emitted from the light emitting element and passing through the capping layer and the encapsulation layer; and
performing a viewing angle color shift dispersion adjustment operation based on determining a dispersion of the viewing angle color shift measured in the visual inspection operation is defective, wherein the viewing angle color shift dispersion adjustment operation comprises forming a color control member on the encapsulation layer.

20. An electronic device comprising:
a display device which displays an image; and
a processor which transmits an image data signal for displaying the image to the display device,
wherein the display device comprises:
a substrate comprising:
a non-emission area; and
a first emission area, a second emission area, and a third emission area adjacent to each other but spaced apart from each other by the non-emission area located between the first emission area, the second emission area, and the third emission area;
a light emitting element located on the substrate;
a capping layer located on the light emitting element;
an encapsulation layer located on the capping layer; and
a color control member located on the encapsulation layer,
wherein the light emitting element comprises:
a functional layer located on the substrate; and
a first light emitting layer, a second light emitting layer, and a third light emitting layer located on the functional layer and overlapping the first emission area, the second emission area, and the third emission area, respectively,
wherein the functional layer has a thickness of 1280 Å to 1480 Å.
